(19) United States
(12) Patent Application Publication
(10) Pub. No.: US 2007/0126103 A1
(43) Pub. Date: Jun. 7, 2007

(54) Microelectronic 3-D package defining thermal through vias and method of making same

(75) Inventor: Wei Shi, Gilbert, AZ (US)

Correspondence Address: INTEL CORPORATION;c/o INTELLEVATE, LLC, P.O. BOX 52050, MINNEAPOLIS, MN, 55402, US

(73) Assignee: Intel Corporation

(21) Appl. No.: 11/292,608

(22) Filed: Dec. 1, 2005

(51) Int. Cl. H01L 23/02

(52) U.S. Cl. 257/686

(57) ABSTRACT

An IC chip, a three dimensional microelectronic package including the IC chip, a system including the microelectronic package, and a method of forming the package. The microelectronic package comprises: a bonding substrate comprising external circuitry; a plurality of IC chips secured in a stack, the plurality comprising a bottom IC chip electrically interconnected to the bonding substrate; the stack further defining a passage therein having a passage inlet and a passage outlet and at least one via configured to guide cooling fluid from one surface of at least one of the IC chips to an opposing surface of the at least one of the IC chips, the passage further being configured to guide a cooling fluid from the passage inlet to the passage outlet. The package further includes electrical interconnects electrically interconnecting respective ones of the IC chips.

### FIELD

Embodiments of the present invention relate to three-dimensional packaging technology.

### BACKGROUND

Conventional microelectronic packages fall into two primary categories; two dimensional packages such as planar based systems and three dimensional packages such as card-on-board packages.

The planar type package is used in high end systems to allow for maximum cooling efficiency. In order to increase circuit density in planar packages (and thereby minimize signal transit delay), manufacturers have continued to reduce the size of various integrated circuit elements and interconnections to the point where the limits of current technology are being reached. In order to increase circuit density and gain other manufacturing advantages, various methods have been explored to interconnect a plurality of integrated circuit chips using horizontal and vertical stacking techniques and three dimensional interconnect modules or “3D packages” which greatly increase integrated circuit surface.

Typically, a 3D package contains either bar dice or multi-chip modules (MCM's) stacked along the z-axis. Because the z-plane technology results in a much lower overall interconnection length, parasitic capacitance and therefore system power consumption can be reduced by as much as 30% or more. However, greater circuit density means increased power density, and thus an increased risk of performance problems caused by a heating of the package. In this respect, reference is made to FIG. 1, which shows an example of a conventional 3D package 100, including a CPU 102 a the bottom, two DRAM modules 104 and 106, a flash module 108 and an analog module 110 stacked thereon, in that order. The CPU is supported on a bonding substrate 112 as shown. Electrical interconnects 114 are provided between package modules. To the extent that packages such as those noted above are typically built on thermal insulators, such as silicon nitride or silicon oxide, heat tends to get trapped into the package, and to negatively affect a performance of the package as a whole.

The thermal management in 3D packages has been addressed in a number of ways by the prior art. First, at the system design level, the prior art has attempted to evenly distribute the thermal energy across the 3-D device surface. Second, at the packaging level, the prior art has either used low thermal resistance substrates such as diamond, or CVD diamond. In addition, the prior art has proposed the use of forced air of liquid coolant to reduce the 3D package temperature, or the use of thermally conductive adhesive and thermal vias between stacked elements to extract heat from the inside of the stack toward its surface. However, disadvantageously, even with the use of the above methods, thermal management of 3D packages remains a problem, especially in view of ever increasing package densification.

The prior art fails to provide a three dimensional package that combines enhanced packaging density with adequate and reliable cooling efficiency.

### BRIEF DESCRIPTION OF THE DRAWINGS

Embodiments of the invention are illustrated by way of example and not by way of limitation in the figures of the accompanying drawings, in which the like references indicate similar elements and in which:

FIG. 1 is a schematic view of a conventional 3D package;

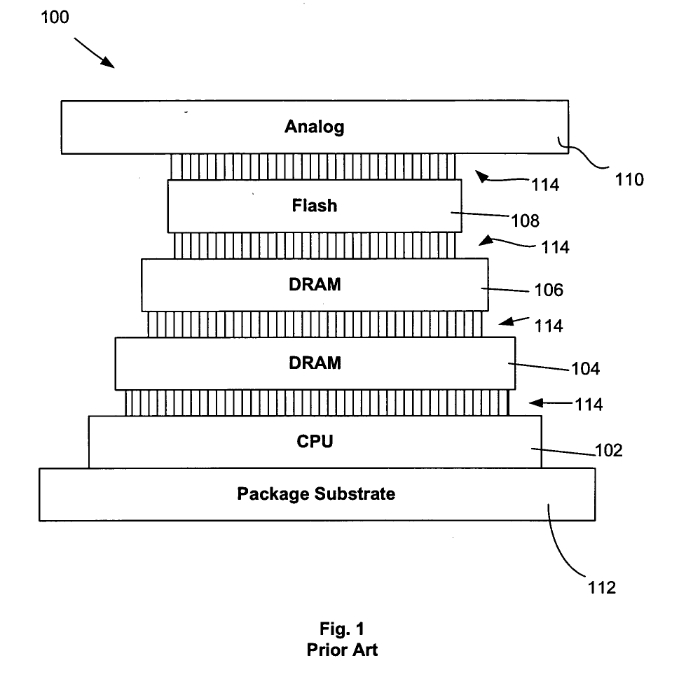

FIG. 2 is a cross-sectional, schematic view of a 3D package according to an embodiment;

FIG. 3 is a view similar to FIG. 2 showing individual IC chips of the package of FIG. 2 prior to their assembly into a stack;

FIGS. 4a and 4b are perspective views of a bottom IC chip and of a top IC chip depicting a transverse conduit in the bottom IC chip according to two respective embodiments;

FIG. 5 is a top plan view of an embodiment of the top most IC chip of the package of FIG. 2;

FIGS. 6a-6e are views similar to FIG. 2 showing stages in the provision of vias in an IC chip according to one embodiment;

FIG. 7 is a view similar to FIG. 2 showing the IC chips of FIG. 3 as having been secured in a stack; and

FIG. 8 is a schematic view of a system incorporating a package according to one embodiment.

### DETAILED DESCRIPTION

An IC chip, a three dimensional microelectronic package including the IC chip, a system including the microelectronic package, and a method of forming the package are disclosed herein.

Various aspects of the illustrative embodiments will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative embodiments. However, it will be apparent to one skilled in the art that the present invention may be practiced without the specific details. In other instances, well-known features are omitted or simplified in order not to obscure the illustrative embodiments.

Various operations will be described as multiple discrete operations, in turn, in a manner that is most helpful in understanding the present invention; however, the order of description should not be construed as to imply that these operations are necessarily order dependent. In particular, these operations need not be performed in the order of presentation.

The phrase “in one embodiment” is used repeatedly. The phrase generally does not refer to the same embodiment, however, it may. The terms “comprising”, “having” and “including” are synonymous, unless the context dictates otherwise.

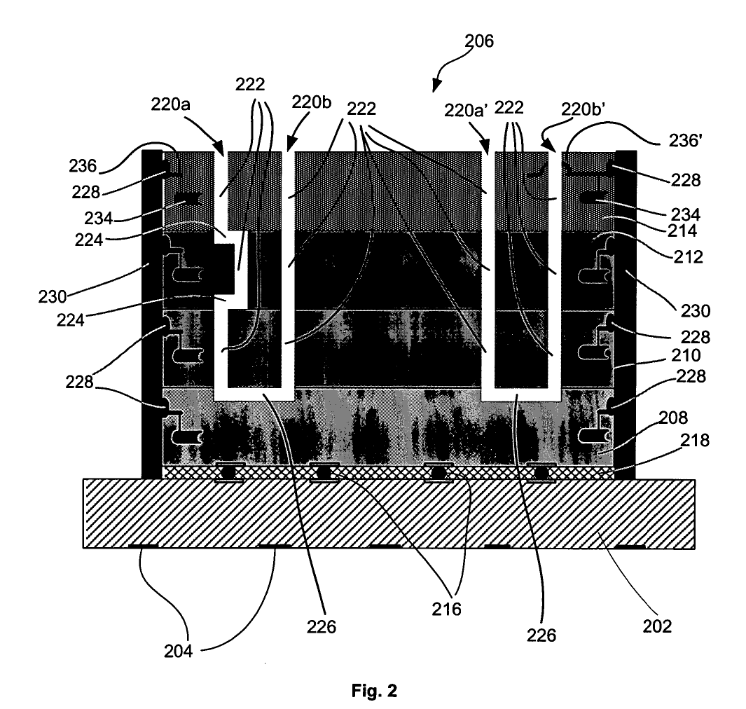

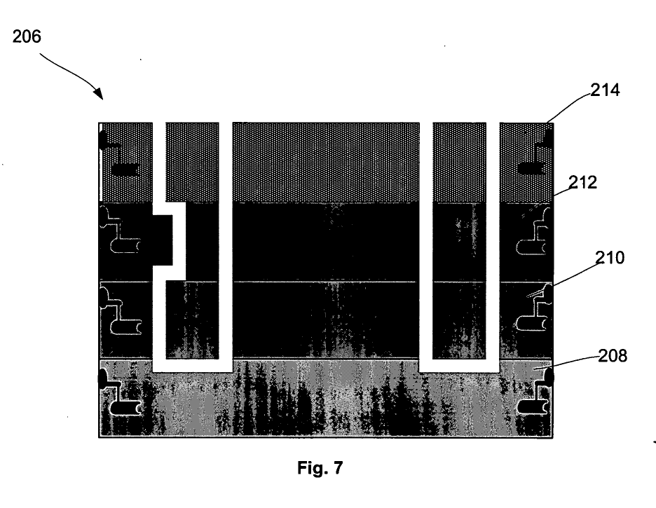

Referring now to FIG. 2, a microelectronic package is shown according to a first embodiment. The package 200 comprises a bonding substrate 202 including lands 204. By “bonding substrate,” what is meant in the context of the instant description is a substrate including lands for connection to external circuitry, and further being adapted to have a 3D chip stack mounted thereon. The package further includes a stack 206 of integrated circuit chips (“IC chips”) secured to one another. A securing of the IC chips in a stack configuration may comprise the use of any of the well known stack formation methods as would be recognized by one skilled in the art, such as, for example, using plasma bonding, as will be explained in further detail in relation to FIG. 7 below. Other securing methods may also be used, such as, for example, methods involving the use of adhesives, as would be recognized by one skilled in the art. The IC chips include a bottom IC chip 208 and first, second and third top IC chips 210, 212 and 214, respectively. By “top IC chip,” what is meant in the context of the instant description is any IC chip that is mounted or adapted to be mounted in a stack form onto the bottom IC chip. Bottom IC chip 208 is electrically interconnected to the bonding substrate 202 as shown. Bottom IC chip 208 may thus comprise electrical contacts in the form of, for example, pads 238 adapted to allow an electrical mounting of the bottom IC chip to bonding substrate 202. An electrical interconnection between the bottom IC chip 208 and the bonding substrate 202 may take place in any conventional manner, such as, for example, by way of solder joints 216 and an underfill material 218 encapsulating the solder joints. In the shown embodiment, each IC chip includes IC chip electrical contacts 228 at sides thereof in order to provide the possibility for edge electrical interconnects 230. Each IC chip further includes a plurality of microelectronic components 234, and electrical interconnections 236 between the components, as shown schematically by way of example with respect to IC chip 214. Some of the electrical interconnects may be rerouted such that they bypass zones corresponding to vias, such as by way of example, electrical interconnects 236′ in IC chip 214. Edge electrical interconnects 230 may be laminated to the sides of the IC chips in a manner to electrically interconnect the IC chips to one another in a predetermined manner. However, embodiments are not so limited, and include within their scope the provision of IC chip electrical contacts and of electrical interconnects in any one of the well known manners. The resulting structure is thus an IC chip stack package 200 comprising a multiple chip stack structure.

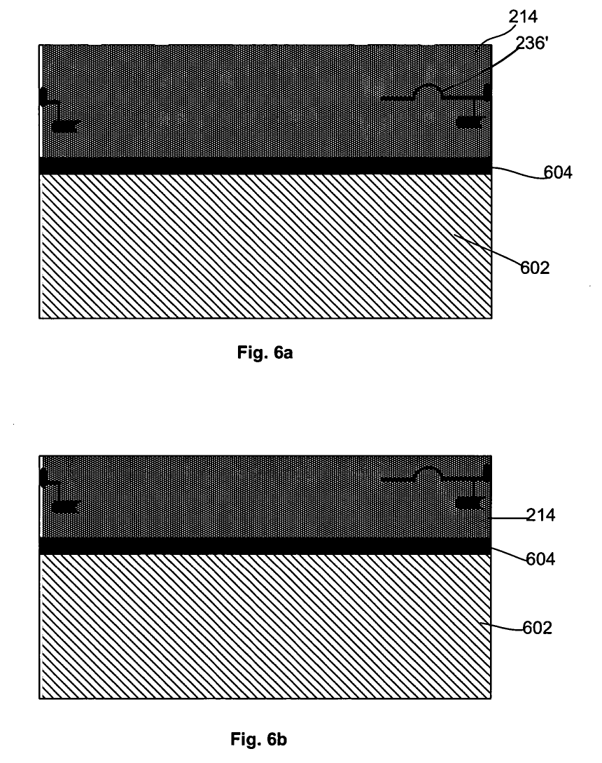

According to the shown cross section of the embodiment of FIG. 2, stack 206 defines therein passages 220 and 220′. In the shown embodiment, each of the passages extends through each of the plurality of IC chips shown, although embodiments are not so limited. Passages 220 and 220′ have, respectively, passage inlets 220a and 220a′, and passage outlets 220b and 220b′ as shown. The passages 220 and 220′ are each configured to guide a cooling fluid therethrough from respective passage inlets 220a and 220a′ to respective passage outlets 220b and 220b′. Thus, each of passages 220 and 220′ is hollow, meaning that it defines a cavity. The cavity according to embodiments may or may not be filled with cooling fluid. Each of passages 220 and 220′, in the shown embodiment, includes a plurality of thermal through vias, or vias, 222 extending through a thickness of respective ones of the IC chips as shown. By “via,” what is meant in the context of the instant description is a through conduit extending through a thickness of an IC chip. Thus, each via 222 is configured to guide cooling fluid from a top surface of an IC chip to an opposing, bottom surface of an IC chip as shown. In the shown embodiment, passage 220 is shown as including vias 222, and, in addition, transverse portions 224 in top IC chip 212. In addition, both passages 220 and 220′ are shown as including transverse portions 226 in the bottom IC chip 208. Transverse portions such as portions 224 of passage 220 may be provided, for example, in order to provide cooling for any hot spots in top IC chip 212. Transverse portions 226 in bottom IC chip 208 may be provided in order to cool bottom IC chip and further in order to redirect cooling fluid in a direction toward passage outlets 220b and 220b′, respectively. As will be explained in further detail in relation to FIGS. 5a and 5b, transverse portion 226 in the bottom IC chip may be configured, by way of example, as a plurality of microchannels, as a flat cavity, or have any other configuration adapted to guide fluid therethrough.

Embodiments are not limited among other things to the provision of a stack having the number of IC chips shown in FIG. 2, to the provision of the number of passages as shown, to the provision of passages having either of the two configurations shown in FIG. 2, or to the provision of side electrical contacts on the IC chips or of edge electrical interconnects. Thus, embodiments comprise within their scope the provision of a stack comprising two or more IC chips, the provision of one or more passages, the provision of one or more passages having any shape as long as the passage has at least one via as defined above, and the provision of electrical contacts and electrical interconnects according to any one of the well known configurations as would be recognized by one skilled in the art. In addition, embodiments are not limited to a provision of a transverse conduit in the IC chips, and comprise within their scope the provision of one or more transverse conduits in the bonding substrate of the package.

As discussed above, densely packed IC chips such as those in a multi-chip stack structure tend to produce an increased amount of heat during normal operation. Therefore, an efficient system of cooling the chip by transferring a substantially amount of heat away from the chip improves the performance and reliability of the chip by reducing self-overheating. Advantageously, a package according to embodiments provides a chip stack defining a passage to allow a thermally conductive or cooling gas mixture or liquid to be circulated therein, such as by way of pumping, the liquid being adapted to thus readily permeate the spaces within the IC chip or chips through which the passage extends, and reach the circuitry therein. Provision of the passage thus substantially reduces thermal hot spots within the multi chip package. Furthermore, IC chips of an entire system may thus be reliably packaged in a single, electronic package in a convenient, highly compact, and cost-efficient manner.

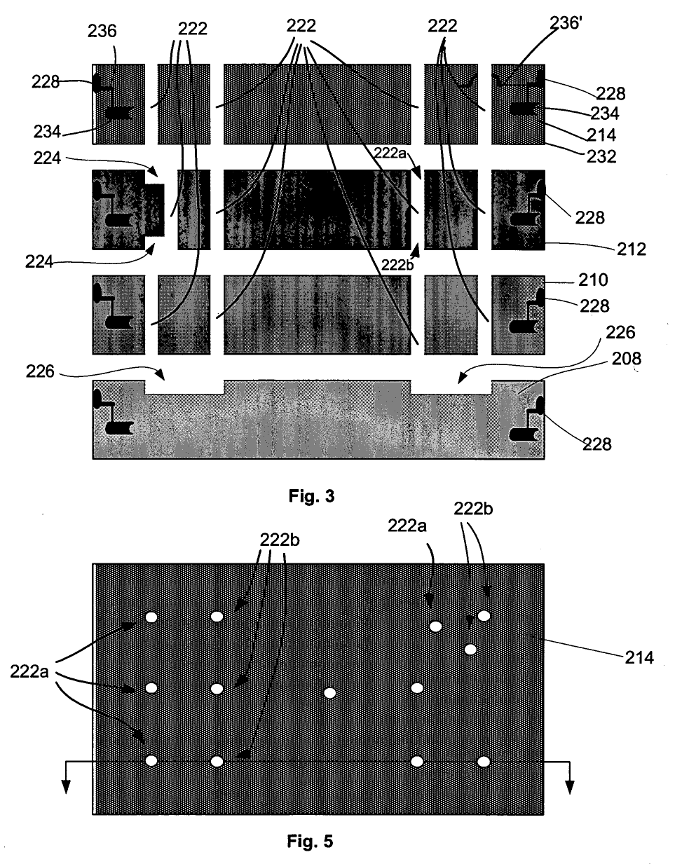

A method embodiment of forming a package such as package 200 of FIG. 2 will now be described in relation to FIGS. 3-6.

Referring first to FIG. 3 by way of example, a stage in the formation of a package according to embodiments comprises providing a plurality of IC chips. An “IC chip” as used herein includes an IC substrate, a plurality of microelectronic components on the IC substrate, electrical interconnections between the components within the chip, and, in addition, electrical contacts disposed to allow an electrical interconnection of the IC chip with other chips, and, optionally, with a bonding substrate. Thus, as seen by way of example in FIG. 3, each of the IC chips shown, such as, for example, top most IC chip 214, includes an IC substrate 232, a plurality of microelectronic components 234, and electrical interconnections 236 between the components. IC components and electrical interconnections between components have been shown only schematically, and it is understood that they can have any configuration as would be within the knowledge of a person skilled in the art. The IC substrate may comprise a silicon substrate, and the IC may thus comprise a variety of integrated circuitry and components, such as, for example, capacitors, resistors, transistors, memory cells, and logic gates, to name just a few. More preferably, the substrate of the IC chip comprises a high resistivity silicon substrate, having a ρ>4000 Ωcm. According to one embodiment, the plurality of IC chips include a CPU chip serving as the bottom IC chip, one or more DRAM chips, a flash memory chip and an analog chip. However, as noted, above, IC chips having any number of functions and circuitry as would be recognized by one skilled in the art would be within the purview of embodiments. The stack may, according to an embodiment, including IC chips sufficient to operate an entire system.

Referring still to FIG. 3 by way of example, a next stage of forming a package such as the package of FIG. 2 may comprise providing a via through at least one of the IC chips, the via having a via inlet at one surface of the IC chip, and a via outlet at an opposing surface of the IC chip. Thus, as seen in FIG. 3, each via 222 extends through each of the IC chips. Each via, as exemplified for example with respect to one of the vias 222 extending through top IC chip 212, includes a via inlet 222a at one surface of the IC chip, and a via outlet 222b at an opposing surface of the IC chip. It is clear from FIG. 3 that a stacking of the respective IC chips shown in the figure would join respective vias with one another to at least in part define the passages 220 and 220′ shown in FIG. 2. Optionally, as seen in FIG. 3, a method embodiment comprises providing a transverse conduit in at least one of the IC chips, the conduit having a component extending in a direction orthogonal to a thickness direction of the at least one of the IC chips. As is clear from the figures, such as from FIG. 3, a “thickness direction” of an IC chip is a direction, as seen in the drawing page, from a top surface of the IC chip vertically down toward a bottom surface of the IC chip. By way of example, a method embodiment may involve the provision of transverse conduits such as transverse conduits 224 on surfaces of IC chip 212. The transverse conduits provided on surfaces of any one of the top IC chips allow the guiding of cooling fluid to predetermined hot spots in the top IC chip or chips having the transverse conduits. In addition, a method embodiment may involve the provision of transverse conduits such as conduits 226 on a surface of the bottom IC chip. The transverse conduits provided on a surface of the bottom IC chip allow among other things the guiding of cooling fluid to cool components within the bottom IC chip, and a switching of a general flow direction of the cooling fluid within a passage from a direction toward the bottom IC chip to a direction away from the bottom IC chip. The provision of transverse conduits in any one of the IC chips may be effected using any one of well known methods, such as, for example, well known methods of providing one or more microchannels on the surface of a substrate, as would be recognized by one skilled in the art.

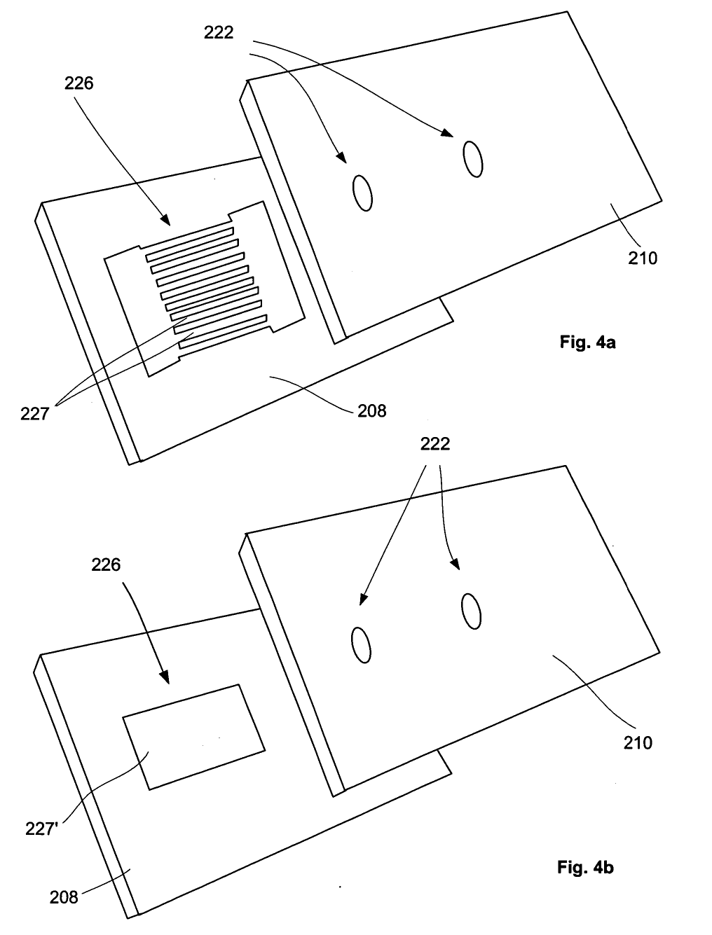

Referring now to FIGS. 4a and 4b by way of example, two possible respective embodiments are shown for a transverse conduit provided in an IC chip, such as, for example, in the bottom IC chip. FIG. 4a shows a perspective view of a bottom IC chip 208 defining a transverse conduit 226 therein including a plurality of microchannels 227 extending in a direction orthogonal to a thickness direction of the bottom IC chip. FIG. 4b, on the other hand, shows a perspective view of a bottom IC chip 208 defining a transverse conduit 226 in the shape of a flat cavity 227′ extending in a direction orthogonal to a thickness direction of the bottom IC chip. Both FIGS. 4a and 4b depict a top IC chip 210 prior to its assembly with bottom IC chip 208, showing not all but only two of the via openings therein. Although FIGS. 4a and 4b show a transverse conduit in the form of microchannels and a flat cavity in a bottom IC chip, it is noted that embodiments are not so limited. A transverse conduit such as those shown in FIGS. 4a and 4b denote a bottom most part of a cooling passage according to embodiments, and need not necessarily be positioned in the bottom IC chip. Thus, embodiments include within their scope a cooling passage such as passage 222 shown in FIG. 2 in which the bottom most part of the passage is in the form of a transverse conduit defined in one of the top IC chips. In other words, embodiments are not limited to a cooling passage that necessarily extends through all of the chips in a stack.

Referring next to FIG. 5 by way of example, a top plan view is shown of an embodiment of the top most IC chip 214. The top most IC chip 214 is shown as including thirteen via openings therein in the form of via inlets 222a and via outlets 222b as shown. As suggested by FIG. 5, according to embodiments, the vias may be provided according to any pattern based on application needs, such as, for example, based on locations within IC chip 214 that need cooling and/or based on locations within IC chips adapted to underlie IC chip 214 in the stack that need cooling, as would be recognized by one skilled in the art. As also suggested in FIG. 5, a cooling passage according to embodiments is not limited to a passage that has a single inlet and a single outlet, and may thus include a passage that bifurcates, such as one with a single inlet and a plurality of outlets, or one with a plurality of inlets and a single outlet, according to application needs.

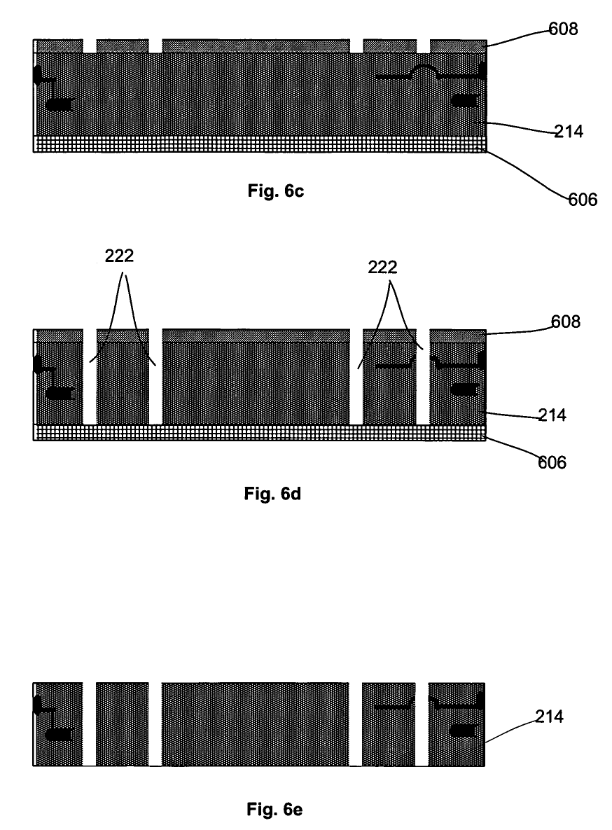

A via may be provided according to embodiments according to any one of well known methods for providing vias. According to a preferred embodiment, the via may be provided using etching. According to a more preferred embodiment, the via may be provided using an Advanced Silicon Etch process (ASE process) as will be described below with respect to FIGS. 6a-6d.

Referring now to FIGS. 6a-6e, a method embodiment of an ASE process is depicted to provide the via the etching may comprise, as depicted in FIG. 6a, first bonding a frontside of an IC chip to a rigid carrier, for example using an adhesive such as wax. Thus, as seen in FIG. 6a by way of example, an IC chip, such as IC chip 214, may be provided, and bonded at its frontside to a rigid carrier such as a glass carrier 602 using a wax layer 604. Preferably, when using the ASE process, the substrate of the IC chip comprises a high resistivity silicon substrate, having a ρ>4000 Ωcm. The glass carrier 602 may have a thickness of, for example, 3 mm. Then, as shown by way of example in FIG. 6b, the substrate of the IC chip 214 may be polished down to a predetermined thickness of the IC chip, such as, for example, to a thickness of about 100 microns. After polishing and cleaning, the thus polished IC chip 214 may be cleaned in any of the well known manners within the knowledge of one skilled in the art. After polishing, as seen in FIG. 6c, passive elements (not shown) on a frontside of the IC chip 214 may be protected with a resist layer, such as resist layer 606. In addition, a backside of the IC chip 214 is provided with a patterned resist layer 608 as shown, the pattern of patterned resist layer 608 corresponding to a pattern of vias to be provided in IC chip 214, such as, for example, the exemplary pattern depicted in FIG. 5. As best seen in FIG. 6c, preferably, a routing of electrical interconnections in an IC chip, such as IC chip, according to an embodiment, may involve a routing of some of the electrical interconnections such that they bypass the vias to be provided, as represented by way of example by rerouted interconnection 236′. Referring next to FIG. 6d, a next stage in provided the via may involve a lithography process to define the via hole on the backside of the IC chip 214. Front to back side alignment (BSA) may be performed using a Suss mask aligner MA6 available from Suss MicroTech GmbH of Munich, Germany. Etching of the via holes may be performed according to any well known method, such as, for example, using an ICP (inductively coupled plasma) etcher, such as one available from Surface Technology Systems, plc of Newport, United Kingdom. An etching process according to an ASE process as described by way of example above may result in a via, such as via 222, having a diameter of about 60 microns and a depth of about 150 microns. Vertical via sidewalls may be achieved using an ASE process an example of which is given above. After provision of the via holes, as shown in FIG. 6e, both resist layers 606 and 608 may be removed to yield the IC chip 214 as shown.

Referring next to FIG. 7 by way of example, a next stage of forming a package such as the package of FIG. 2 may comprise securing the IC chips in a stack, such that the stack defines a passage therein having a passage inlet and a passage outlet, and such that the via constitutes at least a portion of the package. The IC chips may be secured together to form a stack, such as stack 206 including IC chips 208, 210, 212 and 214 as described. Preferably, the IC chips are bonded together using plasma assisted Si—SiO2 or Si—Si bonding, which is well known in the art of wafer-level packaging. For example, with respect to an Si—SiO2 plasma assisted bonding, a thick layer, such as a 4 micron thick layer, of silicon dioxide may be PECVD deposited on a front side of one of the IC chips to be bonded. The deposited silicon dioxide may then be polished, such as on a lapping machine using colloidal silica on an oxide polishing cloth. One micron of oxide may be successfully removed within 30 minutes from a bar silicon wafer having an initial oxide thickness of about 4 microns. Surfaces of the IC chips to be bonded may be exposed to oxygen plasma, for example by using an ICP-RIE (inductively coupled plasma reactive ion etcher) system. Parameters used may include a chamber pressure of about 40 mTorr, an oxygen flow rate of about 48 sccm, RF power of about 15 W, coil power of about 800 W and an exposure time of about 2 minutes. After plasma exposure, the IC chips to be bonded may be rinsed in de-ionized water, dried, and brought into contact at room temperature for bonding. The IC chips may thus be secured to one another using the plasma method outlined above according to a preferred embodiment in order to obtain a stack, such as the stack of FIG. 7. After a securing of the IC chips to one another, optionally, the IC chip edges may be polished to expose IC chip electrical contacts, such as contacts 218.

Referring now back to FIG. 2 by way of example, a next stage of forming a package such as the package of FIG. 2 may comprise providing electrical interconnects electrically connecting respective ones of the IC chips with one another. As seen by way of example in FIG. 2, a preferred embodiment of the electrical interconnects comprises “vertical” or edge electrical interconnects, such as edge electrical interconnects 230. Although FIG. 2 depicts edge electrical interconnects on two sides of the package 200, embodiments pertaining to the provision of edge electrical interconnects encompass the provision of such interconnects on any number of the sides of the package, as would be recognized by one skilled in the art. As seen in FIG. 2, the provision of edge interconnects provides an electrical interconnection between the IC chips by way of side electrical contacts 228 on the IC chips as shown. According to a preferred embodiment, the edge interconnects may be realized along sides of the stack using a high density interconnect process similar to one used to fabricate IC chips, as would be recognized by one skilled in the art. After the formation of the stack, according to the preferred embodiment, sides of the stack may be laminated and then patterned using an electroplated photoresist process, as would be recognized by one skilled in the art. It is noted, however, that embodiments are not limited to the provision of edge electrical interconnects, and comprise within their scope the provision of electrical interconnects configured and disposed in any of the well known manners pertaining to 3D package methods that would be within the knowledge of a person skilled in the art.

Subsequent to a provision of electrical interconnects to electrically interconnect the IC chips with one another, the stack, including the electrical interconnects, may be mounted onto a bonding substrate to electrically interconnect the stack to the bonding substrate. A mounting of the stack may take place according to any one of well known manners, such as, for example, as depicted in the embodiment of FIG. 2, by way of solder joints 216 and an underfill material 218 encapsulating the solder joints. A mounting of the stack yields a package according to embodiments, such as, by way of example, the package embodiment of FIG. 2.

Advantageously, embodiments enable an effective integration of high power IC chips, such as CPU IC chips, into 3D packages. By pumping one phase or two phase cooling into the package along the passages and through the passage vias, more heat can be dissipated from a 3D package as compared with packages of the prior art. In addition, advantageously, a significant amount of heat may be conducted horizontally along the IC chip layers toward the vias, as compared with the necessity of vertical heat conduction through SiO2 and Si3N4 layers in 3D packages of the prior art. In addition, advantageously, embodiments provide for the possibility of effectively eliminating hotspots in a 3D package at different locations on different IC chips according to a power and heat map of the package. The vias may thus advantageously be designed to be closer and denser around the hotspots. In addition, transverse conduits such as microchannels may be designed on a backside of a CPU IC chip in a 3D package as a function of cooling requirements of the CPU IC chip.

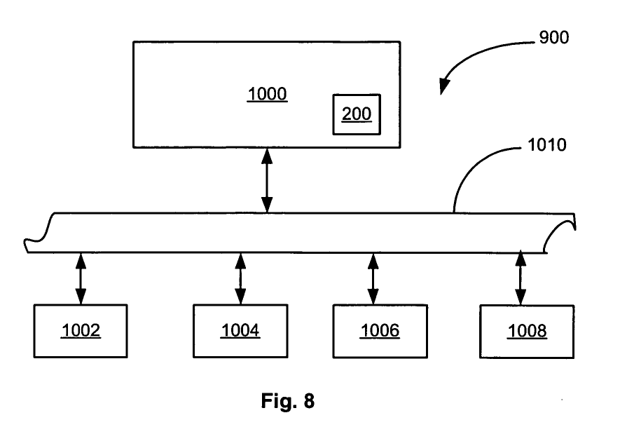

Referring to FIG. 8, there is illustrated one of many possible systems 900 in which embodiments of the present invention may be used. System 900 includes an electronic assembly 1000 including a package such as package 200 of FIG. 2. In one embodiment, the electronic assembly 1000 may include a microprocessor. In an alternate embodiment, the electronic assembly 1000 may include an application specific IC (ASIC). Integrated circuits found in chipsets (e.g., graphics, sound, and control chipsets) may also be packaged in accordance with embodiments of this invention.

For the embodiment depicted by FIG. 8, the system 900 may also include a main memory 1002, a graphics processor 1004, a mass storage device 1006, and/or an input/output module 1008 coupled to each other by way of a bus 1010, as shown. Examples of the memory 1002 include but are not limited to static random access memory (SRAM) and dynamic random access memory (DRAM). Examples of the mass storage device 1006 include but are not limited to a hard disk drive, a compact disk drive (CD), a digital versatile disk drive (DVD), and so forth. Examples of the input/output module 1008 include but are not limited to a keyboard, cursor control arrangements, a display, a network interface, and so forth. Examples of the bus 1010 include but are not limited to a peripheral control interface (PCI) bus, and Industry Standard Architecture (ISA) bus, and so forth. In various embodiments, the system 900 may be a wireless mobile phone, a personal digital assistant, a pocket PC, a tablet PC, a notebook PC, a desktop computer, a set-top box, a media-center PC, a DVD player, and a server.

Although specific embodiments have been illustrated and described herein for purposes of description of the preferred embodiment, it will be appreciated by those of ordinary skill in the art that a wide variety of alternate and/or equivalent implementations calculated to achieve the same purposes may be substituted for the specific embodiment shown and described without departing from the scope of the present invention. Those with skill in the art will readily appreciate that the present invention may be implemented in a very wide variety of embodiments. This application is intended to cover any adaptations or variations of the embodiments discussed herein. Therefore, it is manifestly intended that this invention be limited only by the claims and the equivalents thereof.

What is claimed is:

1. A microelectronic package comprising:
a bonding substrate comprising external circuitry;
a plurality of IC chips secured in a stack, the plurality comprising a bottom IC chip electrically interconnected to the bonding substrate; the stack further defining a passage therein having a passage inlet and a passage outlet, and at least one via configured to guide cooling fluid from one surface of at least one of the IC chips to an opposing surface of the at least one of the IC chips, the passage further being configured to guide a cooling fluid from the passage inlet to the passage outlet;
electrical interconnects electrically interconnecting respective ones of the IC chips.

2. The package of claim 1, wherein the passage comprises a transverse portion defined in the bonding substrate or in at least one of the IC chips, the transverse portion having a component extending in a direction orthogonal to a thickness direction of the bonding substrate or of at least one of the IC chips.

3. The package of claim 2, wherein the transverse portion is defined in the bottom IC chip.

4. The package of claim 2, wherein the transverse portion includes one of a plurality of microchannels and a flat cavity extending in a direction orthogonal to a thickness direction of the bonding substrate or of at least one of the IC chips.

5. The package of claim 1, wherein the at least one via comprises a first via and a second via each extending in a direction parallel to a thickness direction of the stack and through an entire thickness of the at least one IC chip.

6. The package of claim 1, wherein the stack comprises a plurality of IC chips disposed above the bottom IC chip.

7. The package of claim 6, wherein the at least one via comprises a first via and a second via each extending in a direction parallel to a thickness direction of the stack and through an entire thickness of the plurality of IC chips disposed above the bottom IC chip.

8. The package of claim 1, wherein the electrical interconnects comprise edge interconnects disposed on at least one side of the stack.

9. The package of claim 8, wherein the edge interconnects are laminated to the at least one side.

10. An IC chip comprising:
an IC substrate defining a via therethrough, the via having a via inlet at one surface of the substrate and a via outlet at an opposing surface of the IC substrate and being configured to guide a cooling fluid from the via inlet to the via outlet;
a plurality of microelectronic components disposed on the IC substrate;
electrical interconnections provided between the components; and
electrical contacts connected to the components and adapted for connection to external circuitry.

11. The IC chip of claim 10, wherein the via is a straight via.

12. The IC chip of claim 10, wherein the via as at least one via extending in a direction parallel to a thickness direction of the IC substrate.

13. A system comprising:
an electronic assembly including:
a microelectronic package comprising:
a bonding substrate comprising external circuitry;
a plurality of IC chips secured in a stack, the plurality comprising a bottom IC chip electrically interconnected to the bonding substrate; the stack further defining a passage therein having a passage inlet and a passage outlet and at least one via configured to guide cooling fluid from one surface of at least one of the IC chips to an opposing surface of the at least one of the IC chips, the passage further being configured to guide a cooling fluid from the passage inlet to the passage outlet;
electrical interconnects electrically interconnecting respective ones of the IC chips; and
a fluid pump in fluid communication with the passage and adapted to pump cooling fluid therethrough; and
a main memory coupled to the package.

14. The system of claim 13, wherein the passage comprises a transverse portion defined in the bonding substrate or in at least one of the IC chips, the transverse portion having a component extending in a direction orthogonal to a thickness direction of the bonding substrate or of at least one of the IC chips.

15. The system of claim 14, wherein the transverse portion is defined in the bottom IC chip.

16. The system of claim 14, wherein the transverse portion includes a plurality of microchannels extending in a direction orthogonal to a thickness direction of the bonding substrate or of the at least one of the IC chips.

17. The system of claim 13, wherein the at least one via comprises a first via and a second via each extending in a direction parallel to a thickness direction of the stack and through an entire thickness of the at least one IC chip.

18. The system of claim 13, wherein the stack comprises a plurality of IC chips disposed above the bottom IC chip.

19. The system of claim 18, wherein the at least one via comprises a first via and a second via each extending in a direction parallel to a thickness direction of the stack and through an entire thickness of the plurality of IC chips disposed above the bottom IC chip.

20. A method of forming a microelectronic package comprising:
providing a plurality of IC chips including a bottom IC chip adapted to be electrically interconnected to a bonding substrate;
providing a via through at least one of the IC chips, the via having a via inlet at one surface of the IC chip and a via outlet at an opposing surface of the IC chip;
securing the IC chips in a stack, wherein:
the stack defines a passage therein having a passage inlet and a passage outlet and adapted to guide a cooling fluid from the passage inlet to the passage outlet; and
the via constitutes at least a portion of the passage;
providing electrical interconnects electrically interconnecting respective ones of the IC chips;
providing a bonding substrate; and
electrically interconnecting a bottom one of the IC chips to the bonding substrate.

21. The method of claim 20, wherein providing a via comprises etching the via.

22. The method of claim 21, wherein etching the via comprises:
bonding a frontside of the at least one of the IC chips to a rigid carrier;
polishing the at least one of the IC chips to a predetermined thickness after bonding;
removing the at least one of the IC chips from the rigid carrier and cleaning the at least one of the IC chips after polishing;
covering the frontside of the at least one of the IC chips with a frontside resist layer;
covering a backside of the at least one of the IC chips with a patterned resist layer corresponding to a pattern of one of the via inlet and the via outlet;
etching the via holes through the patterned resist layer;
removing the frontside resist layer and the patterned resist layer.

23. The method of claim 21, wherein etching comprises using inductively coupled plasma etching.

24. The method of claim 20, further comprising providing a transverse conduit in the bonding substrate or in at least one of the IC chips having a component extending in a direction orthogonal to a thickness direction of the bonding substrate or of the at least one of the IC chips, the transverse conduit constituting a portion of the passage.

25. The method of claim 24, wherein the transverse portion is defined in the bottom IC chip.

26. The method of claim 24, wherein the transverse portion includes one of a plurality of microchannels and a flat cavity extending in a direction orthogonal to a thickness direction of the bonding substrate or of the at least one of the IC chips.

27. The method of claim 20, wherein providing a via comprises providing a first via and a second via each extending in a direction parallel to a thickness direction of the stack and through an entire thickness of the at least one IC chip.

28. The method of claim 20, wherein the plurality of IC chips comprises a plurality of IC chips disposed above the bottom IC chip.

29. The method of claim 28, wherein securing comprises using plasma assisted bonding.

30. The method of claim 20, wherein providing electrical interconnects comprises providing edge interconnects disposed on at least one side of the stack.
